(19) United States
(12) Patent Application Publication
(10) Pub. No.: US 2007/0145548 A1
(43) Pub. Date: Jun. 28, 2007

(54) Stack-type semiconductor package and manufacturing method thereof

(75) Inventors: Sung Su Park, Seoul (KR); Sang Jae Jang, Seoul (KR); Suk Gu Ko, Seoul (KR); Choon Heung Lee, Gyeonggi-do (KR)

Correspondence Address: GUNNISON MCKAY & HODGSON, LLP;GARDEN WEST OFFICE PLAZA, SUITE 220, 1900 GARDEN ROAD, MONTEREY, CA, 93940, US

(73) Assignee: Amkor Technology, Inc.

(21) Appl. No.: 10/746,024

(22) Filed: Dec. 22, 2003

(51) Int. Cl. H01L 23/02

(52) U.S. Cl. 257/678

(57) ABSTRACT

A stack-type semiconductor package includes a first semiconductor package upon which a second semiconductor package is stacked. A layer of a hardened, insulative material, e.g., a no-flow underfill (NUF) material, is disposed between, and mechanically couples the stacked first and second semiconductor packages. The NUF layer covers portions of the first semiconductor package, e.g., the semiconductor die and the substrate of the first semiconductor package, and solder balls of the second semiconductor package that are fused to the substrate of the first semiconductor package. The NUF material is applied onto the semiconductor die and substrate of the first semiconductor package before the second semiconductor package is stacked on the first semiconductor package, and substantially cures after the solder balls of the second semiconductor package are fused to the substrate of the first semiconductor package.

### BACKGROUND OF THE INVENTION

1. Field of the Invention

The present invention is related to semiconductor packages and to manufacturing methods thereof.

2. Description of the Related Art

One type of conventional semiconductor package, sometimes called a “stack-type” semiconductor package, is manufactured in such a manner that a fully-assembled individual top semiconductor package is stacked on a fully-assembled individual semiconductor bottom semiconductor package. The top and bottom semiconductor packages are electrically and mechanically coupled together at the interface between them. The stack-type semiconductor package subsequently is mounted on an external printed circuit board by electrically coupling interconnects of the bottom semiconductor package, e.g., solder balls, to circuit patterns of the printed circuit board. Hence, this stack-type package has the desirable feature of allowing two semiconductor packages to be mounted in the same printed circuit board area as a single semiconductor package.

In one conventional embodiment, where the top and bottom semiconductor packages of the stack-type semiconductor package each include an encapsulated semiconductor chip mounted on an insulative substrate, and solder balls as interconnects, the solder balls of the top semiconductor package are fused to exposed circuit patterns on a top surface of the substrate of the bottom semiconductor package. The top semiconductor package is mounted over the encapsulant of the bottom semiconductor package, and has its solder balls fused to circuit patterns of the bottom semiconductor package that are exposed outward of the encapsulant of the bottom semiconductor package. In such a design, the solder balls of the top semiconductor package must have an adequate stand-off height so that the top semiconductor package is supported over the encapsulant of the bottom semiconductor package. Otherwise, the encapsulant of the bottom semiconductor package might interfere with the electrical connection of the solder balls of the top semiconductor package to the circuit patterns of the bottom semiconductor package

Unfortunately, such a stack-type semiconductor package presents several problems. For instance, in order to assemble the stack-type package, one must have equipment that can individually handle the two relatively-small packages, and stack them, unit by unit. Second, the solder balls of the top semiconductor package must have a relatively-large stand-off (height) to clear the encapsulant of the bottom semiconductor package. For instance, if the height of the encapsulant is 0.2 mm, then the solder balls of the top semiconductor package must have a greater height of at least 0.25 mm. With such a solder ball height, the top semiconductor package cannot have a solder ball pitch below about 0.5 mm, which excludes many packages from being stacked in this manner. Third, the yield of the stacking process can be adversely effected by manufacturing variations in the height of the encapsulant of the bottom semiconductor package, and defects such as warpage of the substrate of the bottom semiconductor package. Finally, since the top and the bottom semiconductor packages are mechanically and electrically connected to each other only by the reflowed solder balls of the top semiconductor package, physical impacts can separate the packages or create open circuits.

A better, more robust stack-type semiconductor package, one that may be assembled more easily and at lower cost, is therefore desirable.

### SUMMARY

The present invention includes stack-type semiconductor packages, and methods of making such packages.

In one embodiment, a stack-type semiconductor package includes a first semiconductor package including a first semiconductor die electrically coupled to a first substrate of the first semiconductor package. A second semiconductor package is stacked on the first semiconductor package. The second semiconductor package includes an encapsulated second semiconductor chip that is electrically coupled to a second substrate of the second semiconductor package. Interconnects, e.g., solder balls, of the second semiconductor package are electrically coupled to corresponding circuit patterns on a first surface of the first substrate of the first semiconductor package that faces the second semiconductor package. A layer of a hardened electrically insulative material is disposed between the first and second semiconductor packages, and mechanically couples the first and second semiconductor packages.

In one embodiment, the layer of the hardened electrically insulative material is a no-flow underfill material, that covers the first semiconductor die of the first package, the first surface of the first substrate, and the interconnects (e.g., solder balls) of the second semiconductor package that are coupled to the first substrate. The layer of the hardened electrically insulative material may cover a surface of the second substrate of the second semiconductor package that faces the first substrate of the first semiconductor package, and may cover a surface of the second semiconductor chip.

The present invention is best understood by reference to the following detailed description when read in conjunction with the accompanying drawings.

### BRIEF DESCRIPTION OF THE DRAWINGS

FIG. 1 is a cross-sectional side view of a stack-type semiconductor package according to one embodiment of the present invention;

FIG. 2 is a cross-sectional side view of a stack-type semiconductor package according to another embodiment of the present invention;

FIG. 3 is a cross-sectional side view of a stack-type semiconductor package according to another embodiment of the present invention;

FIG. 4A through FIG. 4I are cross-sectional side views of stages in a method for manufacturing a semiconductor package according to one embodiment of the present invention.

FIG. 5 is a cross-sectional side view of a stack-type semiconductor package according to another embodiment of the present invention; and

FIG. 6 is a cross-sectional side view of a stack-type semiconductor package according to another embodiment of the present invention.

Common reference numerals are used throughout the drawings and the detailed descriptions to indicate like elements.

### DETAILED DESCRIPTION

The discussion below and the accompanying figures are examples of stack-type semiconductor packages in accordance with the present invention.

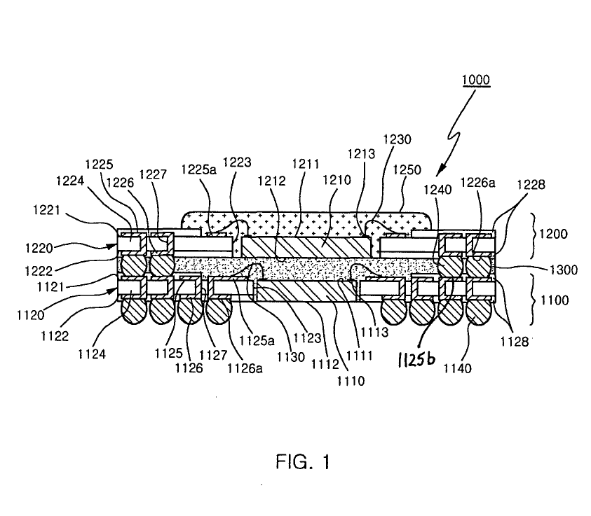

FIG. 1 is a cross-sectional view of a stack-type semiconductor package 1000 according to one embodiment of the present invention. The stack-type semiconductor package 1000 includes a bottom-most first semiconductor package 1100 and a topmost second semiconductor package 1200 that is stacked on the first semiconductor package 1100. The first and second semiconductor packages 1100, 1200 are electrically and mechanically coupled together by a fusing of the solder balls 1240 of the second semiconductor package 1200 to lands 1125b of the circuit patterns 1125 of first semiconductor package 1100, and also are mechanically coupled by a layer 1300 of a hardened, adhesive, electrically insulative material that is coupled between the bottom and top semiconductor packages 1100, 1200 and encapsulates portion of the semiconductor die 1110 and substrate 1120 of the semiconductor package 1100. In this particular example, the layer 1300 is formed of a material known as a no-flow underfill (NUF), but the invention is not so limited. Stack-type semiconductor package 1000 may be mounted on an external printed circuit board by fusing the solder balls 1140 of the first semiconductor package 1100 to circuit patterns of the external printed circuit board.

The first semiconductor package 1100 includes a first semiconductor die 1110, a first substrate 1120 to which the first semiconductor die 1110 is electrically and mechanically coupled, a plurality of first conductive wires 1130 for electrically connecting the first semiconductor die 1110 to the first substrate 1120, and a plurality of first solder balls 1140 electrically connected to the first substrate 1120. The solder balls 1140 serve as external interconnects for the first semiconductor package 1100. Other types of interconnects may be used in alternative embodiments.

The first semiconductor die 1110 includes an approximately planar or a planar first surface 1111 and an approximately planar or planar second surface 1112 opposed to the first surface 1111. The first surface 1111 is the active surface of the first semiconductor die 1110, and includes a plurality of bond pads 1113. The bond pads 1113 may be formed in rows along two or four edges of first surface 1111, or at a center of first surface 1111. The second surface 1112 is the inactive surface of the first semiconductor die 1110.

The first substrate 1120 includes a core insulating layer 1124 between an approximately planar or a planar first surface 1121 and an approximately planar or planar second surface 1122 opposed to the first surface 1121. An aperture 1123 extends through first substrate 1120 from the first surface 1121 to the second surface 1122. The aperture 1123 is rectangular, and is sized to allow the first semiconductor die 1110 to be placed therein.

The first substrate 1120 also includes a plurality of electrically conductive circuit patterns 1125 and 1126 formed on the first and second surfaces 1121 and 1122 thereof, respectively. At least some of the electrically conductive circuit patterns 1125 and 1126 are electrically connected to each other through the first substrate 1120 by electrically conductive vias 1127. The electrically conductive circuit patterns 1125 include at least bond fingers 1125a and lands 1125b. The electrically conductive circuit patterns 1126 include at least lands 1126a. The electrically conductive circuit patterns 1125 and 1126 may be formed of metal, or an electrically-conductive epoxy-based material.

An electrically-insulative solder mask 1128 is provided on the first and second surfaces 1121, 1122 of first substrate 1120. The solder mask 1128 covers the bulk of the electrically conductive circuit patterns 1125 and 1126, except for the bond fingers 1125a and lands 1125b of circuit patterns 1125, and the lands 1126a of the circuit patterns 1126. The first solder balls 1140 are fused to the exposed lands 1126a, and are thereby electrically coupled to circuit patterns 1125 by vias 1127.

The first surface 1111 of the first semiconductor die 1110 is oriented in the same direction as the first surface 1121 of substrate 1120. The bond pads 1113 of the first semiconductor die 1110 and the bond fingers 1125a of the circuit patterns 1125 on the first surface 1121 of the first substrate 1120 are electrically connected to each other by means of conductive wires 1130. The material of the conductive wire 1130 may be aluminum (Al), copper (Cu), gold (Au), silver (Ag) or its equivalent.

The second semiconductor package 1200 includes a second semiconductor die 1210, a second substrate 1220 to which the first semiconductor die is electrically and mechanically coupled, a plurality of second conductive wires 1230 for electrically connecting the second semiconductor die 1210 to the second substrate 1220, an insulative, typically epoxy-based encapsulant 1250 for encapsulating the second semiconductor die 1210 and the second conductive wires 1230, and a plurality of second solder balls 1240 electrically connected to the second substrate 1220. The solder balls 1240 serve as external interconnects for package 1200. Other types of interconnects may be used in alternative embodiments.

The second semiconductor die 1210 includes an approximately planar or a planar first surface 1211 and an approximately planar or planar second surface 1212 opposed to the first surface 1211. The first surface 1211 is the active surface of the second semiconductor die 1210, and includes a plurality of bond pads 1213. The bond pads 1213 may be formed in rows along two or four edges of first surface 1211. The second surface 1212 is the inactive surface of the second semiconductor die 1110.

The second substrate 1220 includes a core insulating layer 1224 between an approximately planar or a planar first surface 1221 and an approximately planar or planar second surface 1222 opposed to the first surface 1221. An aperture 1223 extends through second substrate 1220 from the first surface 1221 to the second surface 1222. The aperture 1223 is rectangular, and is sized to allow the second semiconductor die 1210 to be placed therein.

The second substrate 1220 also includes a plurality of electrically conductive circuit patterns 1225 and 1226 formed on the first and second surfaces 1221 and 1222 thereof, respectively. At least some of the electrically conductive circuit patterns 1225 and 1226 are electrically connected to each other through the second substrate 1220 by electrically conductive vias 1227. The electrically conductive circuit patterns 1225 include at least bond fingers 1225a. The electrically conductive circuit patterns 1226 include at least lands 1226a. The electrically conductive circuit patterns 1225 and 1226 may be formed of metal, or of an electrically-conductive epoxy-based material.

An electrically-insulative solder mask 1228 is provided on the first and second surfaces 1221, 1222 of second substrate 1220. The solder mask 1228 covers the bulk of the electrically conductive circuit patterns 1225 and 1226, except for the bond fingers 1225a and lands 1226a. The second solder balls 1240 are fused to the exposed lands 1226a, and are thereby electrically coupled to circuit patterns 1225 by vias 1227.

The bond pads 1213 of the second semiconductor die 1210 and the bond fingers 1225a of the circuit patterns 1225 on the first surface 1221 of the second substrate 1220 are electrically connected to each other by means of conductive wires 1230. The material of the conductive wire 1230 may be aluminum (Al), copper (Cu), gold (Au), silver (Ag) or its equivalent.

The encapsulant 1250 of second semiconductor package 1200 fills aperture 1223 of the second substrate 1220, in order to protect the second semiconductor die 1210 and the second conductive wires 1230 from the external environment. The encapsulant 1250 covers a subportion-only of the first surface 1221 of second substrate 1220 around aperture 1223, including the bond fingers 1225a of circuit patterns 1225. In an alternative embodiment, encapsulant 1250 may cover all of first surface 1221. A flat bottom surface of encapsulant 1250 and second surface 1212 of semiconductor die 1210 are coplanar with second surface 1222 of second substrate 1220. Encapsulant 1250 does not cover second surface 1212. Encapsulant 1250 is an electrically insulative material, such as a hardened epoxy mold compound.

The second semiconductor package 1200 is stacked on the first semiconductor package 1100. The solder balls 1240 of the second package 1200 are fused to the lands 1125b of the first semiconductor package 1100, thereby mechanically and electrically connecting the second semiconductor package 1200 to the first surface 1121 of the first substrate 1120 of the first semiconductor package 1100. Through the electrical connection of the solder balls 1240 to the lands 1125b, the first and second semiconductor dies 1110, 1210 may be electrically connected, and/or the first solder balls 1140 and the second semiconductor die 1210 may be electrically connected. The first surfaces 1111, 1211 of the first and second semiconductor dies, and the first surfaces 1121, 1221 of the first and second substrates 1120, 1220, all are oriented in a same direction.

Meanwhile, the NUF 1300 is coupled between the bottom semiconductor package 1100 and the top semiconductor package 1200, so that they are mechanically fixed to each other. In particular, the NUF 1300 fills the aperture 1123 in first substrate 1120, and is attached to and covers the first surface 1111 and four peripheral side surfaces of first semiconductor die 1110, the first conductive wires 1130, and the entire first surface 1121 of first substrate 1120 of the bottom semiconductor package 1100. The NUF 1300 also covers the exposed second surface 1212 of second semiconductor die 1210, the bottom flat portion of encapsulant 1250 in aperture 1223 around second semiconductor die 1210, and the entire second surface 1222 of second substrate 1220. The NUF 1300 also adheres to and covers the entire vertical height and circumference solder balls 1240 of second semiconductor package 1200, which are coupled between the first and second semiconductor packages 1100, 1200, and fills the spaces between the solder balls 1240, thereby protecting the solder balls 1240. Second surface 1112 of first semiconductor die 1110 is not covered by NUF 1300, and exposed to the external environment in a common plane with both a bottom flat surface of NUF 1300 around first semiconductor die 1110 and second surface 1122 of first substrate 1120. Second surface 1122 of first substrate 1120 also is not covered by NUF 1300.

The peripheral side walls of first substrate 1120, which extend perpendicularly between the first and second surfaces 1121, 1122 of first substrate 1120, the peripheral side walls of second substrate 1220, which extend perpendicularly between the first and second surfaces 1221, 1222 of second substrate 1220, and the peripheral side surfaces of NUF 1300, are in a common plane, i.e., are vertically coplanar.

As mentioned above, the NUF 1300 is exemplary of an electrically insulative, adhesive, initially viscous but hardenable, resinous material, which typically may be epoxy-based, that may be used to mechanically couple the first and second semiconductor packages 1100, 1200, and to encapsulate elements, such as semiconductor die 1110, solder balls 1240, and first surface 1121, that are contacted by the resinous material.

Generally, a no-flow underfill material like NUF 1300 has properties that allow it to be dispensed in a viscous form on a substrate prior to a step of reflowing solder balls. The no-flow underfill material undergoes minimal curing prior to a solder ball reflow step, and instead substantially and rapidly cures after the maximum solder reflow temperature is reached during the same heating step. The solder ball reflow step and NUF curing step can occur during the same temperature cycle in a single curing oven.

In one embodiment, the NUF 1300 may be one of the materials described in U.S. Pat. No. 6,180,696, which is incorporated herein by reference in its entirety. Therein, it is stated that a no-flow underfill material may obtained by curing a formulation including: (1) an epoxy resin and/or a mixture of several epoxy resins, with the epoxy resin or said mixture having, e.g., more than one 1,2-epoxy group per molecule; (2) an organic carboxylic acid anhydride hardener; (3) a curing accelerator, e.g., a latent curing accelerator adapted to allow a curing reaction of said epoxy resin and/or said mixture to occur at a temperature range of 180 degrees Celsius to 240 degrees Celsius; (4) a self-fluxing agent, e.g., a fluxing agent selected from chemicals having at least one hydroxyl (—OH) group; (5) a viscosity-controlling agent, e.g., fumed silica; (6) a coupling agent, e.g., silane; and (7) a surfactant, e.g., silicone. The curing accelerator may be selected from the group consisting of triphenylphosphine, alkyl-substituted imidazoles, imidazolium salts, onium borates, metal chelates, and mixtures thereof.

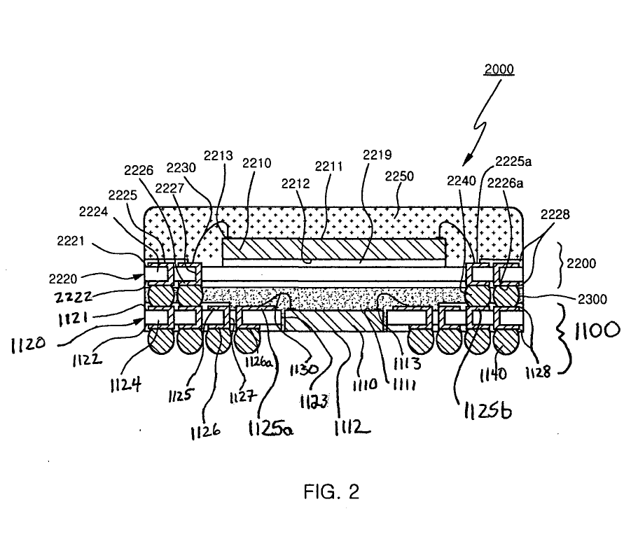

FIG. 2 is a cross-sectional side view of a stack-type semiconductor package 2000 according to another embodiment of the present invention. Stack-type semiconductor package 2000 includes a topmost second package 2200 that is stacked on, and electrically and mechanically coupled to, a bottom-most first semiconductor package 1100. The second semiconductor package 2200 is electrically and mechanically coupled to first semiconductor package 1100 by the fused connection between solder balls 2240 of second semiconductor package 2200 and lands 1125b of first circuit patterns 1125 of first semiconductor package 1100. The first and second semiconductor packages 1100 and 2200 of stack-type semiconductor package 2000 are mechanically coupled by an NUF 2300, which is identical in composition and function as NUF 1300 of FIG. 1.

The first semiconductor package 1100 of stack-type semiconductor package 2000 of FIG. 2 is the same as the first semiconductor package 1100 of FIG. 1, and has the same reference numbers. Hence the description of semiconductor package 1100 provided above applies and is incorporated here by reference.

Topmost second semiconductor package 2200 of stack-type semiconductor package 2000 is very similar to second semiconductor package 1200 of FIG. 1. Features of semiconductor package 2200 that correspond to features of second semiconductor package 1200 of FIG. 1 have the same reference number plus 1000 (e.g., second semiconductor die 2210 of second semiconductor package 2200 of FIG. 2 is the same as second semiconductor die 1210 of second semiconductor package 1200 of FIG. 1). To the extent the semiconductor packages 2200 and 1200 are the same, the above description of semiconductor package 1200 applies, and is incorporated herein by reference. Accordingly, we will focus the present discussion on the differences between the second semiconductor packages 2200 and 1200 of FIGS. 2 and 1, respectively, in our discussion of stack-type semiconductor package 2000 of FIG. 2.

In particular, second semiconductor package 2200 of FIG. 2 lacks an aperture through the second substrate 2200 similar to aperture 1223 of second semiconductor package 1200 of FIG. 1. Instead, the second semiconductor die 2210 is mounted to the first surface 2221 of substrate 2220 of second semiconductor package 2200, and is coupled thereto by an adhesive layer 2219, which may be a die attach paste, or a double-sided adhesive film. The encapsulant 2250 covers the second semiconductor die 2210 and the entire first surface 2221 of second substrate 2200 of second semiconductor package 2200.

In addition, because the second semiconductor package 2200 of FIG. 2 lacks an aperture through its substrate 2220, the NUF 2300 does not contact the second surface 2212 of the second semiconductor die 2210.

The NUF 2300 is coupled between the bottom semiconductor package 1100 and the top semiconductor package 2200, so that they are mechanically fixed to each other. The NUF 2300 fills the aperture 1123 in first substrate 1120, and is attached to and covers the first surface 1111 and peripheral side surfaces of first semiconductor die 1110, the first conductive wires 1130, and the entire first surface 1121 of first substrate 1120 of the bottom semiconductor package 1100. The NUF 2300 also is attached to and covers the entire second surface 2222 of second substrate 2220 of second semiconductor package 2200. The NUF 2300 also is attached to and covers the solder balls 2240 of second semiconductor package 2200, and fills the spaces between the solder balls 2240, thereby protecting the solder balls 2240. Second surface 1112 of first semiconductor die 1110 of semiconductor package 1100 is not covered by NUF 2300, and exposed to the external environment in a common plane with both a bottom flat surface of NUF 2300 around first semiconductor die 1110 and second surface 1122 of first substrate 1120. Second surface 1122 of first substrate 1120 also is not covered by NUF 2300.

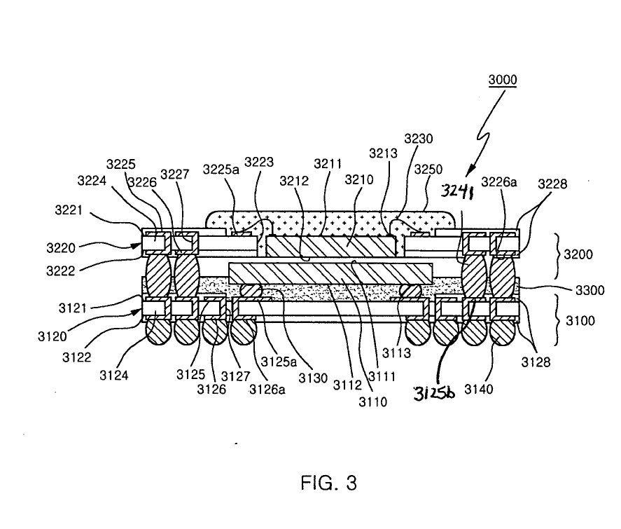

FIG. 3 is a cross-sectional side view of a stack-type semiconductor package 3000 according to another further embodiment of the present invention. The stack-type semiconductor package 3000 includes a bottom-most first semiconductor package 3100, a top-most second semiconductor package 3200 that is stacked on, and mechanically and electrically coupled to, the first semiconductor package 3100, and a NUF 3300 that overlies the entire first surface 3121 of first substrate 3120 of first semiconductor package 3100.

The bottom first semiconductor package 3100 of stack-type semiconductor package 3000 includes a first semiconductor die 3110, a first substrate 3120 to which the first semiconductor die 3110 is electrically and mechanically coupled, a plurality of first conductive bumps 3130 for electrically connecting the first semiconductor die 3110 to the first substrate 3120, and a plurality of first solder balls 3140 electrically connected to the first substrate 3120. The solder balls 3140 serve as external interconnects for bottom package 3100. Other types of interconnects may be used in alternative embodiments.

The first semiconductor die 3110 includes an approximately planar or a planar first surface 3111 and an approximately planar or planar second surface 3112 opposed to the first surface 3111. The first surface 3111 is the inactive surface of the first semiconductor die 3110. The second surface 3112 is the active surface of the first semiconductor die 3110 and includes a plurality of bond pads 3113. The bond pads 3113 may be formed in rows along two or four edges of second surface 3112 or at the center of second surface 3112, or may be formed in a checkerboard grid on second surface 3112.

The first substrate 3120 includes an insulating layer 3124 having an approximately planar or a planar first surface 3121, and an approximately planar or planar second surface 3122 opposed to the first surface 3121. Unlike semiconductor package 1100 of FIGS. 1 and 2, semiconductor package 3100 lacks an aperture through its substrate 3120.

The first substrate 3120 also includes a plurality of electrically conductive circuit patterns 3125 and 3126 formed on the first and second surfaces 3121 and 3122 thereof, respectively. At least some of the electrically conductive circuit patterns 3125 and 3126 are electrically connected to each other through the first substrate 3120 by electrically conductive vias 3127. The electrically conductive circuit patterns 3125 include at least bond fingers 3125a and lands 3125b. The electrically conductive circuit patterns 3126 include at least lands 3126a. The electrically conductive circuit patterns 3125 and 3126 may be formed of metal, or an electrically-conductive epoxy-based material.

An electrically-insulative solder mask 3128 is provided on the first and second surfaces 3121, 3122 of first substrate 3120. The solder mask 3128 covers the bulk of the electrically conductive circuit patterns 3125 and 3126, except for the bond fingers 3125a and lands 3125b of circuit patterns 3125, and the lands 3126a of the circuit patterns 3126. The first solder balls 3140 are fused to the exposed lands 3126a, and are thereby electrically coupled to circuit patterns 3125 by vias 3127.

The bond pads 3113 of the first semiconductor die 3110 and the bond fingers 3125a of the circuit patterns 3125 on the first surface 3121 of the first substrate 3120 are electrically connected to each other in a flip chip style connection by means of the conductive bumps 3130. The material of the conductive bumps 3130 may be lead-tin, gold, or silver, or may be an electrically-conductive epoxy-based, silicone-based, or other polymer-based material. The juxtaposed second surface 3112 of first semiconductor die 3110 and the first surface 3121 of first substrate 3120 are spaced apart by the vertical height of conductive bumps 3130.

The topmost second semiconductor package 3200 of stack-type semiconductor package 3000 is very similar to second semiconductor package 1200 of FIG. 1. Features of second semiconductor package 3200 that correspond to features of second semiconductor package 1200 of FIG. 1 have the same reference number plus 2000 (e.g., second semiconductor die 3210 of second semiconductor package 3200 of FIG. 3 is the same as second semiconductor die 1210 of second semiconductor package 1200 of FIG. 1). To the extent the semiconductor packages are the same, the above description of semiconductor package 1200 applies, and is incorporated herein by reference. Accordingly, we will focus the present discussion on the differences between the second semiconductor packages 3200 and 1200 of FIGS. 3 and 1, respectively, in our discussion of stack-type semiconductor package 3000 of FIG. 3.

A difference between semiconductor package 3200 of FIG. 3 and semiconductor package 1200 of FIG. 1 concerns the size and shape of the conductive interconnects that electrically couple the stacked packages. In particular, the interconnects of first semiconductor package 3200 of FIG. 3 are columnar pillars 3241, which have a greater stand-off height than the solder balls 1240 of semiconductor package 1200 of FIG. 1.

The NUF 3300 is the same material and has the same function as NUF 1300 of FIG. 1. The NUF 3300 is disposed between the first semiconductor package 3100 and the second semiconductor package 3200 of stack-type semiconductor package 3000, and mechanically couples the first and second packages 3100, 3200 together. In particular, the NUF 3300 is attached to and covers the entire first surface 3121 of first substrate 3120, and the active second surface 3112 of the first semiconductor die 3110 of the bottom semiconductor package 3100. The NUF 3300 also is attached to and covers the conductive bumps 3130, and fills the spaces between the conductive bumps 3130 and between second surface 3112 and the underlying juxtaposed portion of the first surface 3121 of first substrate 3120. The NUF 3300 has a vertical height over first surface 3121 such that the NUF 3300 is attached to and covers only a lower subportion of the height of the interconnect pillars 3241, and only a lower subportion of the height of the four peripheral sides of the first semiconductor die 3110. The NUF 3300 fills the spaces between the lower subportions of the height of the interconnect pillars 3241. The NUF 3300 does not cover the upper subportion of the height of the interconnect pillars 3241 or the upper subportion of the height of the four peripheral sides of first semiconductor die 3110, and does not contact the inactive first surface 3111 of first semiconductor die 3110. Nor does the NUF 3300 contact the second surface 3212 of second semiconductor die 3210 nor the second surface 3222 of second substrate 3220 of second semiconductor package 3200.

The mechanical coupling of first semiconductor package 3100 to second semiconductor package 3200 via NUF 3300 is through the coupling of NUF 3300 between the first surface 3121 of first substrate 3120 of first semiconductor package 3100 and the lower subportion of the interconnect pillars 3241 of second semiconductor package 3200. The fact that NUF 3300 does not contact second surface 3212 of semiconductor die 3210, the upper subportion of interconnect pillars 3241, or the first surface 3111 of first semiconductor die 3110 allows for excellent heat radiation from semiconductor package 3000.

In an alternative embodiment, the NUF 3300 covers some, but not all, of the first surface 3111 of the first semiconductor die 3110.

In a further embodiment, the NUF 3300 fills the entire space between first and second semiconductor packages 3100 and 3200, including covering the first surface 3111 of the first semiconductor die 3110, and the second surfaces 3212 and 3222 of second semiconductor die 3210 and second substrate 3220, respectively, of second semiconductor package 3200.

In a further alternative embodiment, the first semiconductor die 3110 is inverted so that its bond pads 3113 face second semiconductor package 3200, and is electrically coupled with low loop conductive wires to the bond fingers 3125a of the first substrate 3120, as in FIG. 1. In such an embodiment, the NUF 3300 may cover the bond pads 3113 and conductive wires coupled to the bond fingers 3125a.

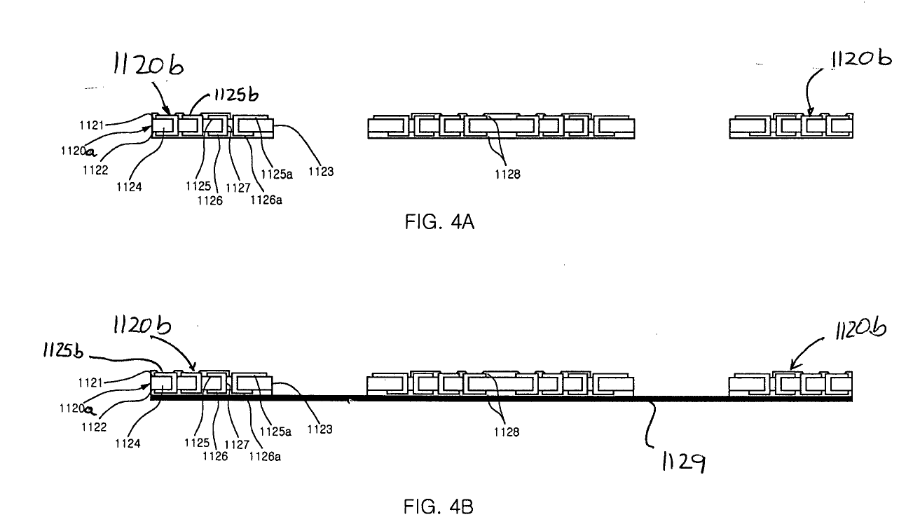

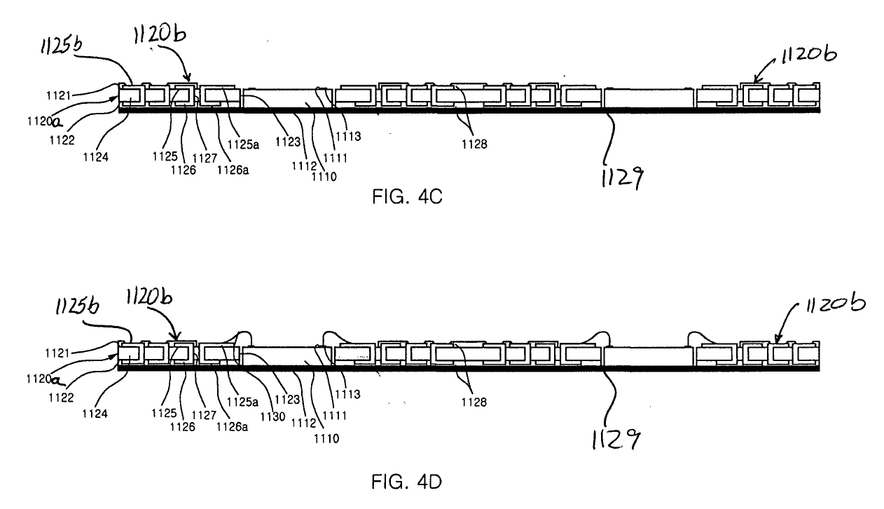

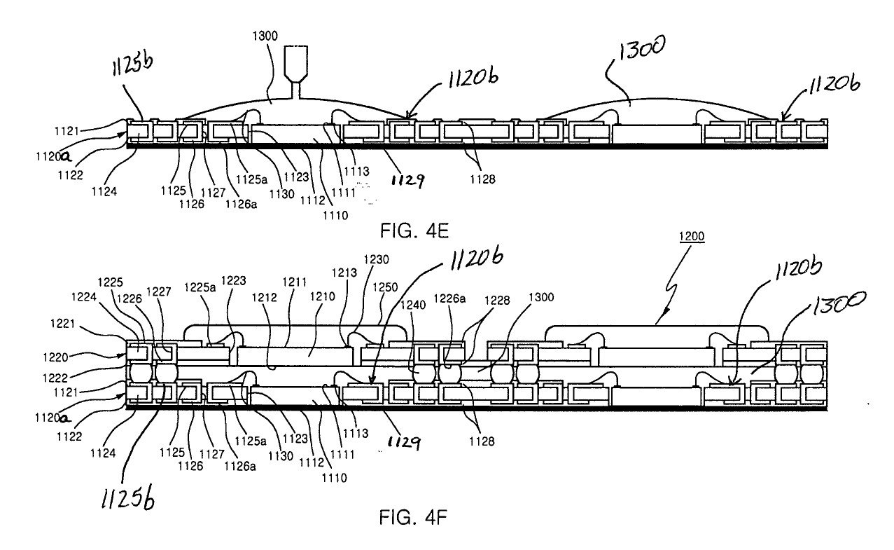

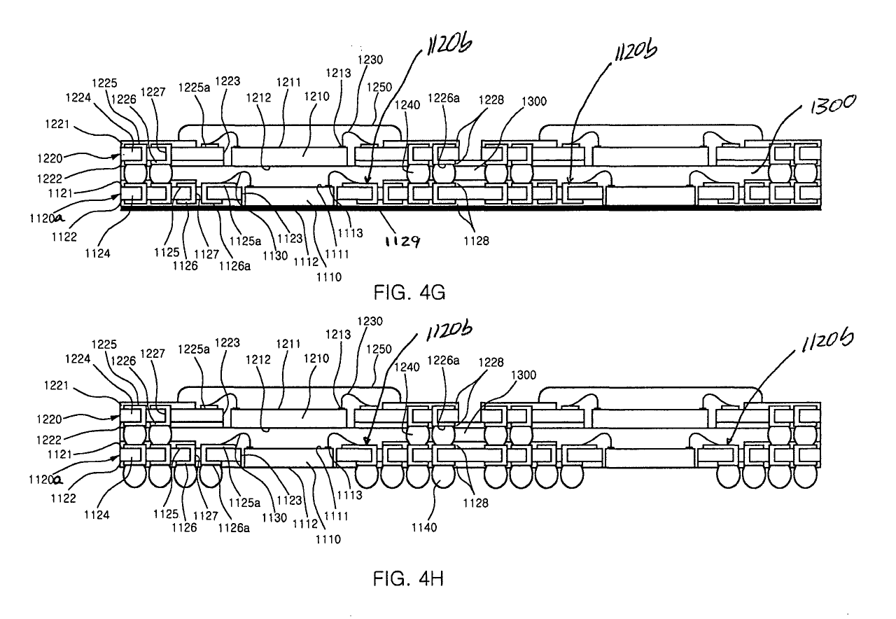

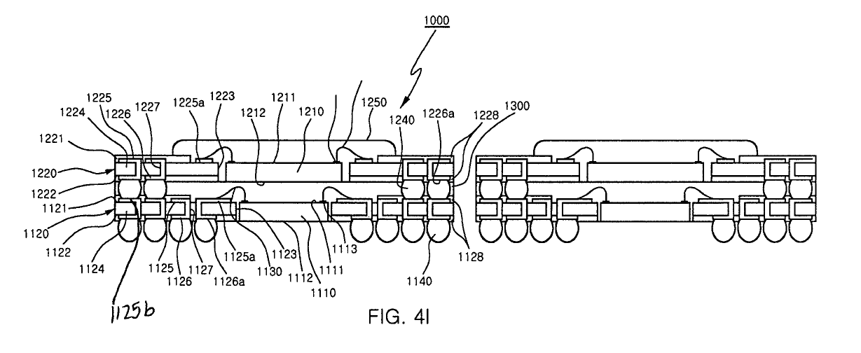

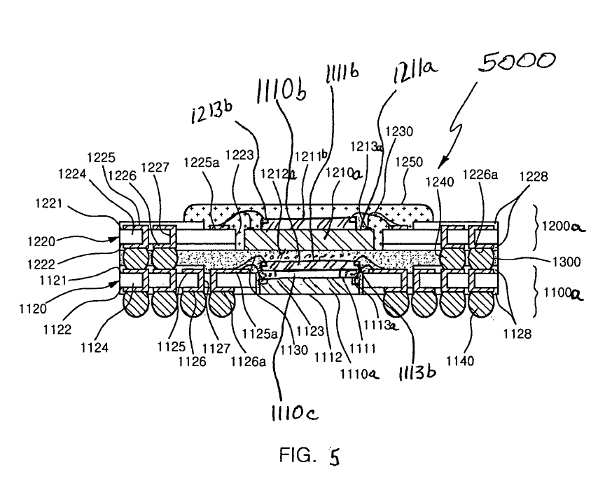

FIGS. 4A through 4I illustrate stages in an exemplary process for manufacturing a plurality of stack-type semiconductor packages, in accordance with the present invention. In this example, a plurality of the stack-type semiconductor packages 1000 of FIG. 1 are manufactured in parallel in a single process. Steps in the exemplary method, which are elaborated below with reference to the figures, include providing a substrate strip 1120a including a plurality of package sites 1120b, attaching a cover lay tape 1129 over the plurality of package sites 1120b, installing a semiconductor die 1110 at each package site 1120b, bonding conductive wires 1130 to each semiconductor die 1110, applying a NUF 1300 over the substrate strip so as to cover each of the semiconductor dies 1110, stacking a second semiconductor package 1200 onto the substrate strip 1120a at each package site 1120b, reflowing the solder balls 1240 of each of the second semiconductor packages 1200, curing the NUF 1300, detaching the cover lay tape 1129, fusing the solder balls 1140 to the lands 1126a at each package site 1120b, and singulating the substrate strip 1120a to obtain singulated ones of the plural stack-type semiconductor packages 1000.

Referring to FIG. 4A, a step of providing the substrate strip 1120a is illustrated. The substrate strip 1120a includes a plurality of package sites 1120b and a plurality of apertures 1123, with one aperture 1123 at a center of each of the package sites 1120b. The package sites 1120b may be arrayed in a single row, or in plural rows and plural columns. Each package site 1120b includes one not-yet-singulated first substrate 1120 of first semiconductor package 1100 of FIG. 1 with the above-described features of a first surface 1121, a second surface 1122 opposed to the first surface 1121, a core insulating layer 1124 between the first and second surfaces 1121, 1122, and a central aperture 1123. A plurality of electrically conductive circuit patterns 1125 and 1126 are formed on the first and second surfaces 1121 and 1122, respectively, around the aperture 1123. The bond fingers 1125a are disposed near the aperture 1123. Some of the electrically conductive circuit patterns 1125 and 1126 are electrically connected to each other through conductive vias 1127. A respective layer of an insulative solder mask 1128 is coated on the bulk of the electrically conductive circuit patterns 1125 and 1126, except for the bond fingers 1125a, and lands 1125b, 1126a.

Referring to FIG. 4B, the step of attaching the cover lay tape 1129 is illustrated. The cover lay tape 1129 is approximately the same size as substrate strip 1120a, and is bonded on the second surface 1122 of the substrate strip 1120a, so that a contiguous single cover lay tape 1129 covers the respective aperture 1123 of all of the package sites 1120b of the substrate strip 1120a. The cover lay tape 1129 and its adhesive are formed in a manner that allows the cover lay tape 1129 to be detached from substrate strip 1120a, such as with the application of heat, ultraviolet light, and so forth. Alternatively, a plurality of smaller cover lay tapes may be provided, each sized to cover only one aperture 1123, and a respective one of the cover lay tapes may be attached over the aperture 1123 at each package site 1120b. In such a case, the cover lay tape need not be removed, provided that the lands 1126a are unobstructed.

Referring to FIG. 4C, the step of installing the semiconductor dies 1110 is illustrated. As shown in FIG. 4C, plural semiconductor dies 1110 are provided. One of the semiconductor dies 1110 is placed onto the cover lay tape 1129 within the aperture 1123 of each of the plural package sites 1120b. The semiconductor die 1110 includes a first surface 1111, a second surface 1112 opposed to the first surface 1111, and a plurality of bond pads 1113. The second surface 1112 of each semiconductor die 1110 is coupled to the cover lay tape 1129. In one embodiment, the cover lay tape 1129 is sufficiently tacky that the semiconductor die 1110 is coupled thereto.

Referring to FIG. 4D, the step of electrically coupling the respective first semiconductor die 1110 to the substrate 1120 of the respective package site 1120b of the substrate strip 1120a is illustrated. In this example, each of the bond pads 1113 of each the semiconductor dies 1110 is electrically coupled to a respective one of the bond fingers 1125a of the electrically conductive circuit patterns 1125 of the respective substrate 1120 by a respective one of a plurality of conductive wires 1130.

Referring to FIG. 4E, the step of applying the NUF 1300 is illustrated. A plurality of globs of viscous NUF 1300 are applied to the substrate strip 1120a, with one glob of the NUF 1300 applied over the center aperture 1123 of each package site 1120b. The glob of the NUF 1300 is applied onto the first surface 1111 of the first semiconductor die 1110 and fills the aperture 1123 of the respective package site 1120a, contacting the cover lay tape 1129 fully around the perimeter of the first semiconductor die 1110 within the aperture 1123. The NUF 1300 is applied in an amount so that it fully covers the semiconductor die 1110 and the conductive wires 1130 bonded thereto. In this example, the NUF 1300 glob covers a subportion-only of the first surface 1121 of the first substrate 1120 so that the bond fingers 1125a of the first circuit patterns 1125 are covered by the NUF 1300 but the lands 1125b are not covered. However, in an alternative embodiment, the glob of NUF 1300 may cover all of the first surface 1121 at the package site 1120b, including the bond fingers 1125a and the lands 1125b.

Referring to FIG. 4F, the step of stacking the plural second semiconductor packages 1200 on the substrate strip 1120a is illustrated. A singulated one of the semiconductor packages 1200 is stacked on each of the package sites 1120b. The respective semiconductor package 1200 is compressed on the respective uncured or minimally cured glob of NUF 1300 of the respective package site 1120b of the substrate strip 1120a. During the stacking step, the solder balls 1240 each are contacted with a juxtaposed corresponding one of the lands 1125b of the electrically conductive circuit patterns 1125 of the first surface 1121 of the substrate 1120 of the package site 1120b through the NUF 1300. As a result of this compressing, the NUF 1300 evenly disperses in all lateral directions on the first surface 1121 of first substrate 1120 of the package site 1120b of the substrate strip 1120a. Hence, the NUF 1300 completely fills the vertical space between the facing surfaces of the second semiconductor package 1200, including second surface 1222 of second substrate 1220 and second surface 1212 of second semiconductor die 1210, and the first semiconductor package 1100, including the first surface 1121 of the first substrate 1120 and the first surface 1111 of the first semiconductor die 1110. In addition, the solder balls 1240 are covered with the NUF 1300, and the spaces between the solder balls 1240 are filled with the NUF 1300.

Referring to FIG. 4G, the step of reflowing the solder balls 1240 of the second packages 1200 is illustrated. There is minimal curing of the NUF 1300 before the solder balls 1240 are reflowed, as is described in U.S. Pat. No. 6,180,696. By heating the solder balls 1240 to a predetermined temperature for a predetermined time, the solder balls 1240 reflow, and each of the solder balls 1240 of each of the plural second semiconductor packages 1200 become fused to the underlying land 1125b of electrically conductive circuit patterns 1125 of the substrate 1120 of the respective package site 1120b of the substrate strip 1120a, so that the solder balls 1240 and the lands 1125b of the first and second semiconductor packages 1100, 1200, respectively, can be firmly electrically and mechanically connected to each other. Further, any NUF 1300 between any one of the solder balls 1240 and the underlying land 1125b is dispersed outwardly during the reflow step, allowing the solder ball 1240 to make an electrical connection with the land 1125b without interference with the NUF 1300. During, or just after the solder ball reflow, the NUF 1300 cures through the continued application of heat, leading to a hardening of the NUF 1300.

Referring to FIG. 4H, the step of detaching the cover lay tape 1129 from the substrate strip 1120a is performed, and then the solder balls 1140 are fused to the lands 1126a of the substrate 1120 of each of the package sites 1120b of the substrate strip 1120a. In one embodiment, heat or ultraviolet light are applied to the cover lay tape 1129 to facilitate a subsequent peeling of the cover lay tape 1129 from substrate strip 1120a. The removal of the cover lay tape 1129 exposes the lands 1126a, the second surface 1122 of the substrate 1120, and the second surface 1112 of the first semiconductor die 1110. Thereafter, the solder balls 1140 may be fused to the lands 1126a by a conventional process.

Referring to FIG. 4I, the step of singulating individual packages 1000 is illustrated. The substrate strip 1120 is singulated through the space between the facing sides of the substrates 1220 of the adjacent pairs of the second semiconductor packages 1200, and through underlying boundary regions of the package sites 1120b of the substrate strip 1120a, thereby singulating each of the plural stack-type semiconductor packages 1000. The singulating step may be performed, for example, by cutting through the NUF 1300 and the substrate strip 1120a with a saw. The saw may also shave off peripheral portions of the second substrate 1220, so that each of the rectangular-perimeter stack-type semiconductor packages 1000 has a straight side surface between the first surface 1221 of the second semiconductor package 1200 and the second surface 1121 of the first semiconductor package 1100. The corresponding peripheral sides of the first semiconductor package 1100, the NUF 1300, and the second semiconductor package 1200 may be coplanar. Alternatively, the singulating step may be performed with a laser. If desired, prior to the singulating step, a marking step, in which a predetermined letter or picture is marked on the encapsulant 1250 of the top semiconductor package 1200, can be conducted.

In an alternative embodiment, the plural second semiconductor packages 1200, which themselves may be formed from a single substrate strip akin to substrate strip 1120a that includes a plurality of package sites, may not be singulated before the stacking of the second semiconductor packages 1200 on the substrate strip 1120a. In other words, the second semiconductor packages 1200 may have interconnected substrates 1220, so that all of the second semiconductor packages are simultaneously stacked on the corresponding package sites 1120b of the substrate strip 1120a in a single step. In such an embodiment, the second semiconductor packages 1200 may be separated from each other during the same singulation step (see FIG. 4I) that severs the substrate strip 1120a and the NUF 1300 between the package sites 1120b to singulate the semiconductor packages 1000.

The stack type semiconductor packages 2000 and 3000 of FIGS. 2 and 3, respectively, may be manufactured by slightly modifying the above-describe method of making stack-type semiconductor package 1000.

For instance, stack-type semiconductor package 2000 of FIG. 2 may be made by the process of FIGS. 4A-4I, except that a plurality of the semiconductor packages 2200 are stacked on the substrate strip 1120a, with one semiconductor package 2200 at each of the package sites 1120b.

Similarly, stack-type semiconductor package 3000 of FIG. 3 may be made by the process of FIGS. 4A-4I, with the following changes. First, a different substrate strip is provided, in that the substrate strip included interconnected first substrates 3120 of FIG. 3. Second, the NUF 3300 is applied to the package sites of the substrate strip prior to the placement of the first semiconductor chip 3110 using a flip chip style placement. The conductive bumps 3130, which may be initially provided the bond pads 3113 of the first semiconductor chip 3110, are pressed through the uncured or minimally cured NUF 3300 so that each of the conductive bumps 3130 contacts a juxtaposed one of the bond fingers 3125a. Third, a plurality of the semiconductor packages 3200 are provided, each of which has the elongated interconnect pillars 3241. Each of the semiconductor packages 3200 are stacked on one of the package sites of the substrate strip so that each of the interconnect pillars 3241 extend through the NUF 3300 and contact a respective one of the lands 3125b. The NUF 3300 is applied in an amount that does not allow for the NUF 3300 to contact the second substrate 3220 of the second semiconductor package 3200. Finally, the conductive bumps 3130 and the interconnect pillars 3241 are simultaneously reflowed by application of heat so as to make an electrical connection with the juxtaposed bond fingers 3125a and lands 3125b, respectively. The NUF 3300 substantially cures during, or just after, the reflow process.

Further embodiments of stack-type semiconductor packages may be obtained by varying the style of the two individual packages that are stacked, and electrically and mechanically coupled, to form the stack-type semiconductor package.

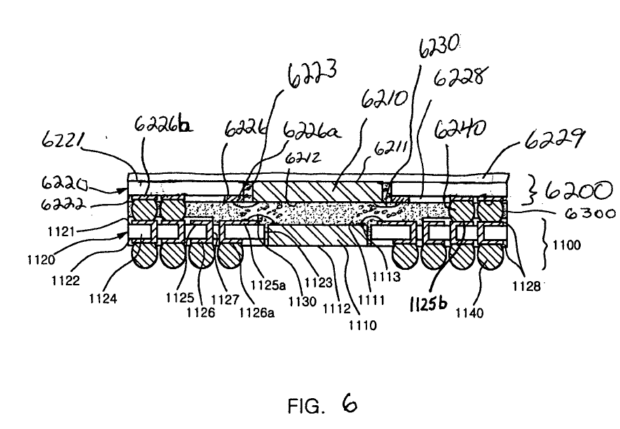

For instance, FIG. 5 shows an embodiment of a stack-type semiconductor package 5000 that is identical to stack-type semiconductor package 1000 of FIG. 1, except that the two stacked packages, denoted as packages 1100a and 1200a, each include a plurality of stacked semiconductor chips in their central aperture 1123 and 1223, respectively. In particular, the bottom-most semiconductor package 1100a includes two semiconductor dies 1110a and 1110b that are the same size, are stacked one on top of the other within aperture 1123, are coupled together by an insulative adhesive spacer 1110c, and have their active first surfaces 1111, 1111b facing in a same direction as first surface 1121 of the first substrate 1120. The bond pads 1113a, 1113b of both of semiconductor dies 1110a, 1110b are electrically coupled by conductive wires 1130 to bond fingers 1125a. NUF 1300 covers both of the stacked semiconductor dies 1110a, 1110b and fills the aperture 1123 around the stacked semiconductor dies 1110a, 1110b. Meanwhile, the topmost semiconductor package 1200a includes two semiconductor dies 1210a and 1210b that are stacked one on top of the other within aperture 1223, are coupled together by an insulative adhesive layer, and have their active first surfaces 1211a, 1211b facing in a same direction as first surface 1221 of the second substrate 1220. The bond pads 1213a, 1213b of semiconductor dies 1210a, 1210b are electrically coupled by conductive wires 1230 to bond fingers 1225a. The topmost semiconductor die 1210b is smaller than the bottom-most semiconductor die 1210a, and fits entirely within the bond pads 1213a of the semiconductor die 1210a.

Similarly, FIG. 6 shows an embodiment of a stack-type semiconductor package 6000 that includes a bottom-most first semiconductor package 1100, as in FIG. 1, and a topmost second semiconductor package 6200. In this embodiment, the second semiconductor package 6200 includes conductive circuit patterns (i.e., conductive circuit patterns 6226) only on one surface of its substrate 6220, namely on second surface 6222 which faces the first semiconductor package 1100. The second surface 6212 (which is the active surface) and bond pads 6213 of the second semiconductor die 6210 face the first semiconductor package 1100, and low loop conductive wires 6230 electrically couple the bond pads 6213 to bond fingers 6226a of the circuit patterns 6226. Solder balls 6240 are electrically coupled between lands 6226b of the second semiconductor package 6200 and lands 1125b of the first semiconductor package 1100. Conductive wires 1130 also are low loop wires. NUF 6300 covers the first and second semiconductor dies 1110, 6210, the solder balls 6240, and the facing surfaces 1121, 6222 of the first and second substrates 1120, 6220, respectively. NUF 6300 also fills the substrate apertures 1123, 6223 within which the first and second semiconductor dies 1110, 6210 are disposed. The NUF 6300 does not cover the inactive second surface 1112 of the first semiconductor die, the inactive second surface 6211 of the second semiconductor die 6210, the second surface 1122 of first substrate 1120, or the first surface 6221 of the second substrate 6220. In other words, the NUF 6300 is the only encapsulant for the semiconductor dies of the two stacked semiconductor packages 1100 and 6200. To make the semiconductor package 6000, a cover lay tape 6229 like cover lay tape 1129 of FIG. 4B is used to assemble second semiconductor package 6200. The encapsulation of the second semiconductor die 6210 by the NUF 6300 occurs in a stacking step like that of FIG. 4F, which compresses and evenly spreads an uncured or minimally cured gob of NUF 6300. The cover layer tape 6229 may remain on the semiconductor package 6000 after singulation, as shown, or may be removed.

This disclosure provides exemplary embodiments of the present invention. The scope of the present invention is not limited by these exemplary embodiments. Numerous variations, whether explicitly provided for or implied by the specification, such as variations in structure, dimension, type of material and the manufacturing process may be implemented by one who is skilled in the art, in view of this disclosure.

1. A semiconductor package comprising:
a first semiconductor die and a first substrate,
wherein the first substrate includes opposed first and second surfaces and an insulative core layer therebetween, first circuit patterns on the first surface of the substrate, and second circuit patterns on the second surface of the substrate, with some of the first and second circuit patterns being electrically coupled through the first substrate, and
wherein the first semiconductor die is electrically coupled to the first circuit patterns;
a second semiconductor die and a second substrate,
wherein the second substrate includes opposed first and second surfaces and an insulative core layer therebetween, electrically conductive circuit patterns at least on the second surface of the second substrate, and electrically conductive second interconnects that are coupled to the circuit patterns of the second surface and extend from the second surface,
wherein the second semiconductor die is electrically coupled to the circuit patterns of the second substrate, and
wherein the second substrate and second semiconductor die are stacked on the first substrate, and the second interconnects are soldered to the first circuit patterns of the first substrate, thereby electrically and mechanically coupling the second substrate to the first substrate; and
a first layer of an electrically insulative, hardened resin-based first material, wherein the first layer is a no-flow underfill material,
wherein the first layer covers the first semiconductor die, the first surface of the first substrate, and the second interconnects, thereby mechanically coupling the second substrate to the first substrate.

2. (canceled)

3. The semiconductor package of claim 1, wherein the first layer is formed of a material that does not cure or cures minimally below a temperature of 180 degrees Celsius.

4. The semiconductor package of claim 1, wherein the first semiconductor die is disposed in a first aperture through the first substrate, and includes an active surface oriented in a same direction as the first surface of the first substrate, and an opposite inactive surface, the first layer fills the first aperture around the first semiconductor die, and the inactive surface of the first semiconductor die is exposed through the first layer in a common plane with the second surface of the first substrate.

5. The semiconductor package of claim 4, wherein the first layer covers the second surface of the second substrate.

6. The semiconductor package of claim 5, wherein the first layer covers a surface of the second semiconductor die.

7. The semiconductor package of claim 6, wherein the second semiconductor die is disposed in a second aperture through the second substrate.

8. The semiconductor package of claim 7, wherein the second substrate includes circuit patterns on the first and second surfaces of the second substrate, with some of the circuit patterns of the first surface being electrically coupled through the second substrate to some of the circuit patterns of the second surface, and
wherein the second semiconductor die is encapsulated in an insulative encapsulant that fills the second aperture, the second semiconductor die includes an active surface oriented in a same direction as the first surface of the second substrate, and an opposite inactive surface that is in a common plane with the second surface of the second substrate, the inactive surface being the surface covered by the first layer, and the second semiconductor die is electrically coupled to the circuit patterns of the first surface of the second substrate.

9. The semiconductor package of claim 7, wherein the first layer fills the second aperture, and covers an active surface of the second semiconductor.

10. The semiconductor package of claim 4, wherein the first layer does not contact the second surface of the second substrate nor the second semiconductor die.

11. The semiconductor package of claim 1, wherein the first semiconductor die is electrically coupled to the first circuit patterns in a flip chip connection, with an active surface of the first semiconductor die being oriented in an opposite direction as the first surface of the first substrate.

12. The semiconductor package of claim 11, wherein the first layer is coupled between the entire active surface of the first semiconductor die and a juxtaposed portion of the first surface of the first substrate.

13. The semiconductor package of claim 11, wherein the first semiconductor die includes an inactive surface opposite the active surface, and at least a portion of the inactive surface is uncovered by the first layer.

14. The semiconductor package of claim 11, wherein the second interconnects are metal pillars.

15. The semiconductor package of claim 1, wherein the second interconnects are solder balls or pillars.

16. The semiconductor package of claim 1, wherein the first semiconductor die is supported in a first aperture of the first substrate by the first layer, and the second semiconductor die is supported in a second aperture of the second substrate by an encapsulant.

17. The semiconductor package of claim 16, wherein the first layer contacts a surface of the second semiconductor die.

18. The semiconductor package of claim 1, wherein the first layer covers only a lower portion of a height of the second interconnects between the first and second substrates, and does not cover an upper portion of the height of the second interconnects.

19. The semiconductor package of claim 1, further comprising a third semiconductor die stacked on one of the first and second semiconductor dies.

20. The semiconductor package of claim 1, wherein the first and second semiconductor dies each include an active surface, and the active surfaces are oriented in a same direction.

21. The semiconductor package of claim 1, wherein the first and second semiconductor dies each include an active surface, and the active surfaces are oriented in an opposite direction.

22. A semiconductor package comprising:
a first semiconductor package comprising a first semiconductor die having a plurality of bond pads, a first substrate electrically connected to the first semiconductor die by a plurality of first conductive wires, and a plurality of first solder balls electrically connected to the first substrate;
a second semiconductor package stacked on the first semiconductor package, and comprising a second semiconductor die having a plurality of bond pads, a second substrate electrically connected to the second semiconductor die by means of a plurality of second conductive wires, an encapsulant material covering the second semiconductor die, the second conductive wires, and at least a portion of the second substrate, and a plurality of second solder balls electrically coupled to the second semiconductor die via the second substrate and fused to the first substrate so as to electrically couple the second substrate with the first substrate; and
a layer of an insulative NUF (No-Flow Underfill) material disposed between and mechanically coupling the first and second semiconductor packages, the NUF layer covering the first semiconductor die of the first semiconductor package, the first conductive wires, and the second solder balls.

23. The semiconductor package of claim 22, wherein in the first semiconductor package:
the first semiconductor die comprises an active surface with the plurality of bond pads thereon, and an opposite inactive surface,
the first substrate comprises an insulating layer between opposed first and second surfaces, and an aperture extending from the first surface to the second surface wherein the first semiconductor die is disposed, and a plurality of electrically conductive circuit patterns formed on the first and second surfaces of the insulating layer, wherein some of the circuit patterns of the first surface are electrically coupled to some of the circuit patterns of the second surface by vias through the substrate; and
the plurality of first conductive wires electrically connect the bond pads of the first semiconductor die to the electrically conductive circuit patterns of the first surface of the first substrate; and
the first solder balls are electrically connected to the electrically conductive circuit patterns formed at the second surface of the first substrate.

24. The semiconductor package of claim 23, wherein the second solder balls of the second semiconductor package are fused to the electrically conductive circuit patterns formed at the first surface of the first substrate.

25. The semiconductor package of claim 23, wherein the second surface of the first semiconductor die of the first semiconductor package is exposed through the NUF layer.

26. The semiconductor package of claim 23, wherein in the second semiconductor package:
the second semiconductor die comprises an active surface with the plurality of bond pads thereon, and an opposite inactive surface;
the second substrate comprises an insulating layer between opposed first and second surfaces, and an aperture extending from the first surface to the second surface wherein the second semiconductor die is disposed, and a plurality of electrically conductive circuit patterns formed on the first and second surfaces of the insulating layer, wherein some of the circuit patterns of the first surface are electrically coupled to some of the circuit patterns of the second surface by vias through the substrate; and
the plurality of second conductive wires electrically connect the bond pads of the second semiconductor die to the electrically conductive circuit patterns of the first surface of the second substrate;
the second solder balls are electrically connected to the electrically conductive circuit patterns formed at the second surface of the second substrate; and
the encapsulant fills the second aperture around the second semiconductor package.

27. The semiconductor package of claim 22, further comprising a third semiconductor die stacked on one of the first and second semiconductor dies.

28. The semiconductor package of claim 23, wherein in the second semiconductor package the second semiconductor die is mounted on the first surface of the second substrate and is electrically coupled to electrically conductive circuit patterns on the first surface of the second substrate.

29-39. (canceled)

40. The semiconductor package of claim 22, wherein peripheral sides of the first and second substrates and the NUF layer are coplanar.

41. The semiconductor package of claim 23, wherein the NUF layer fills the aperture around the first semiconductor die.

42. The semiconductor package of claim 22, wherein the NUF layer covers a surface of the second substrate.

43. The semiconductor package of claim 42, wherein the NUF layer covers a surface of the second semiconductor die.

44. The semiconductor package of claim 22, wherein the NUF layer does not contact a first surface of the second substrate.

45. The semiconductor package of claim 22, wherein the first semiconductor die is supported in a first aperture of the first substrate by the NUF layer, and the second semiconductor die is supported in a second aperture of the second substrate by the encapsulant.

46. The semiconductor package of claim 45 wherein the NUF layer contacts a surface of the second semiconductor die.

47. The semiconductor package of claim 22 wherein the first and second semiconductor dies each include an active surface, and the active surfaces are oriented in a same direction.

48. A semiconductor package comprising:
a first substrate comprising:
opposed first and second surfaces and an insulative core layer therebetween;
first circuit patterns on the first surface of the first substrate;
second circuit patterns on the second surface of the first substrate, with some of the first and second circuit patterns being electrically coupled through the first substrate;
a first semiconductor die electrically coupled to the first circuit patterns by first conductive wires, the first semiconductor die being disposed in a first aperture through the first substrate,
a second substrate comprising:
opposed first and second surfaces and an insulative core layer therebetween;
first circuit patterns on the first surface of the second substrate;
second circuit patterns on the second surface of the second substrate, with some of the first and second circuit patterns being electrically coupled through the second substrate;
a second semiconductor die electrically coupled to the first circuit patterns of the second substrate by second conductive wires, the second semiconductor die being disposed in a second aperture through the second substrate;
wherein the second substrate and second semiconductor die are stacked on the first substrate, and interconnects are soldered to the first circuit patterns of the first substrate and the second circuit patterns of the second substrate, thereby electrically and mechanically coupling the second substrate to the first substrate;
a first layer of an electrically insulative, hardened resin-based first material, wherein the first layer is a no-flow underfill material, the first layer covering the first semiconductor die, the first surface of the first substrate, and the interconnects, thereby mechanically coupling the second substrate to the first substrate, the first layer filling the first aperture around the first semiconductor die, and an inactive surface of the first semiconductor die is exposed through the first layer in a common plane with the second surface of the first substrate; and
an encapsulant material covering the second semiconductor die, the second conductive wires, and at least a portion of the second substrate, the encapsulant material filling the second aperture.

49. The semiconductor package of claim 48 wherein the active surface of the first semiconductor die is oriented in a same direction as the first surface of the first substrate.

50. The semiconductor package of claim 48 where the second semiconductor die includes an active surface oriented in a same direction as the first surface of the second substrate, and an opposite inactive surface that is in a common plane with the second surface of the second substrate, the inactive surface being covered by the first layer.
